(19) United States
(12) Patent Application Publication
(10) Pub. No.: US 2015/0362548 A1
(43) Pub. Date: Dec. 17, 2015

(54) WAFER MAP IDENTIFICATION SYSTEM FOR WAFER TEST DATA

(71) Applicants: KWUN JONG CHEN, (US); SIGNALITY SYSTEM ENGINEERING CO., LTD., HSINCHU COUNTY (TW); HUNG WU MACHINE CO., LTD., HSIN CHU CITY (TW)

(72) Inventor: KWUN JONG CHEN, HSINCHU COUNTY (TW)

(21) Appl. No.: 14/473,053

(22) Filed: Aug. 29, 2014

(30) Foreign Application Priority Data
Jun. 11, 2014 (TW) 103120241

(51) Int. Cl. G01R 31/28; G01R 31/26

(52) U.S. Cl. CPC G01R 31/2831; G01R 31/2607

(57) ABSTRACT

A wafer map identification system for wafer test data includes a capturing unit configured to collect the test data of each wafer chip from the wafer testing device; an execution interface for receiving the test data from the capturing unit and generating a wafer map, the wafer map defining a plurality of color blocks with respect to locations of the test chips, each of the color blocks having a color defined by a grade of the respective test chip. Moreover, each color block reveals the associated test data as being pointed.

### BACKGROUND OF THE INVENTION

1. Field of the Invention

The present invention relates to a wafer test system, and more particularly to a wafer map identification system for wafer test data.

2. Description of the Prior Art

FIG. 11 shows a conventional wafer map 9, a test wafer has a plurality of test chips with individual physical locations within an area 91. The test chips each has an individual numeral code corresponding to a grade of the respective test chip such that the same grades of the test chips are represented by the same numeral codes; the different grades of the test chips are represented by the different numeral codes.

Although the aforementioned wafer map could be identified by the numeral codes with respect to the grades of the test chips, the numerous numeral codes may be disordered to identify the numeral code of each test chip; and the test data of the specific test chip could not be directly read is necessary. The test data of the specific test chip should be read via data sheet, which is bothersome in semiconductor production. The present invention is, therefore, arisen to obviate or at least mitigate the above mentioned disadvantages.

### SUMMARY OF THE INVENTION

An object of the present invention is to provide an improved wafer map identification system for wafer test data so as to rapidly identify the wafer map.

To achieve the above and other objects, a wafer map identification system for wafer test data, wherein a test wafer is divided into a plurality of test chips, each of the test chips being tested by a wafer testing device for electrical property to obtain the test data, the wafer map identification system comprising:

a capturing unit configured to collect the test data of each wafer chip from the wafer testing device;

an execution interface for receiving the test data from the capturing unit and generating a wafer map, the wafer map defining a plurality of color blocks with respect to locations of the test chips, each of the color blocks having a color defined by a grade of the respective test chip such that the same grades of the test chips have the same colors, the different grades of the test chips have the different colors; wherein each color block reveals the associated test data as being selected by a pointer.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

FIG. 1 is a schematic view for showing the transmission between the capturing unit and the execution interface of present invention;

FIG. 2 is a schematic view for showing the initial state of the execution interface;

FIG. 3 is a schematic view for showing a confirmation window is appeared after one of the wafer files is selected;

FIG. 4 is a schematic view for showing a partial enlarged view of the wafer map;

FIG. 5 is a schematic view for showing one of the color blocks is selected, and the execution interface displays a window for the test data thereafter;

FIG. 6 is a schematic view for showing the execution interface is provided to display plural windows for the test data of the color blocks;

FIG. 7 illustrates that the execution interface is reduced for showing more regions of the wafer map;

FIG. 8 illustrates that the execution interface displays more windows for showing the test data of more color blocks;

FIG. 9 illustrates that the execution interface displays a plurality of curve charts of test results of whole test wafer under various parameters;

FIG. 10 illustrates that the execution interface displays the window for showing the test data and displays the curve charts simultaneously; and

FIG. 11 is a prior art.

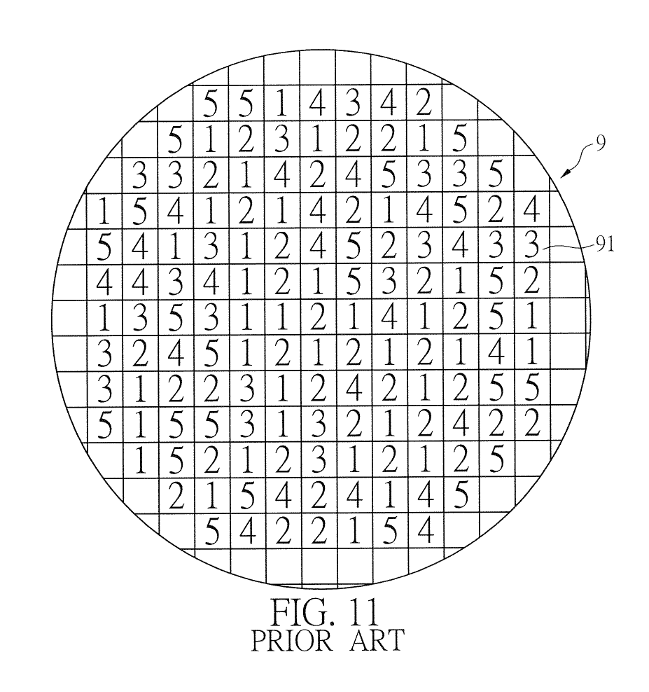

### DETAILED DESCRIPTION OF THE PREFERRED EMBODIMENTS

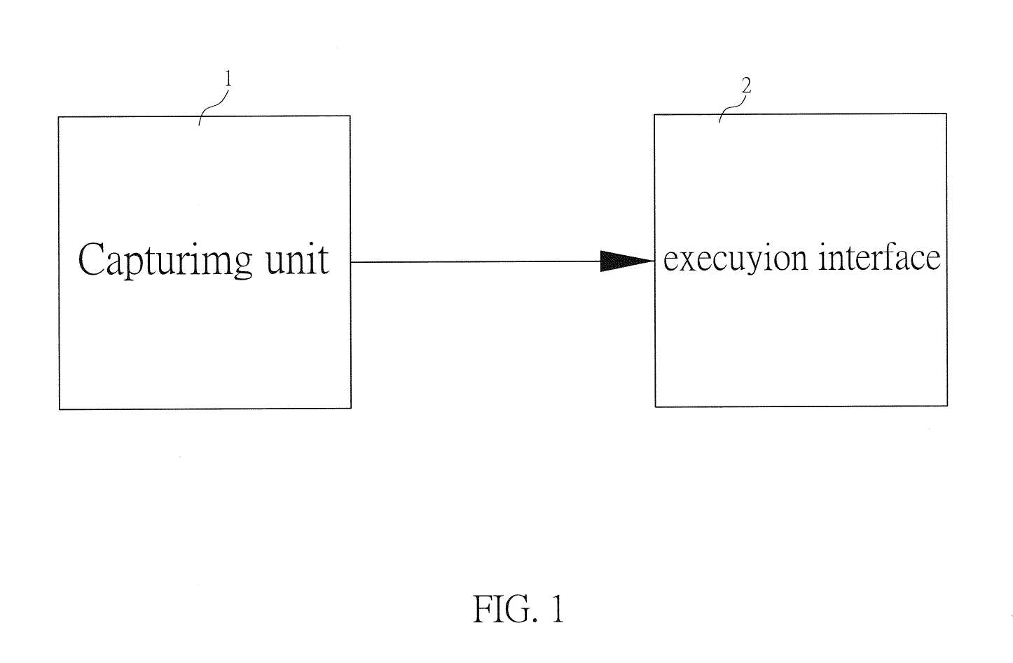

Referring to FIGS. 1-10, a wafer map identification system for wafer test data is provided in accordance with a preferred embodiment of the present invention.

A test wafer is divided into a plurality of test chips, and each of the test chips is tested by a wafer testing device for electrical property to obtain said test data. As shown in FIG. 1, the wafer map identification system comprises a capturing unit 1 and an execution interface 2.

The capturing unit 1 is configured to collect the test data of each wafer chip from the wafer testing device. The execution interface 2 is configured to receive the test data from the capturing unit 1 and to generate a wafer map according to the test wafer. The wafer map defines a plurality of color blocks with respect to locations of the test chips. Each of the color blocks has a color defined by a grade of the respective test chip such that the same grades of the test chips have the same colors; the different grades of the test chips have the different colors. Furthermore, each of the color blocks reveals the associated test data as being selected by a pointer.

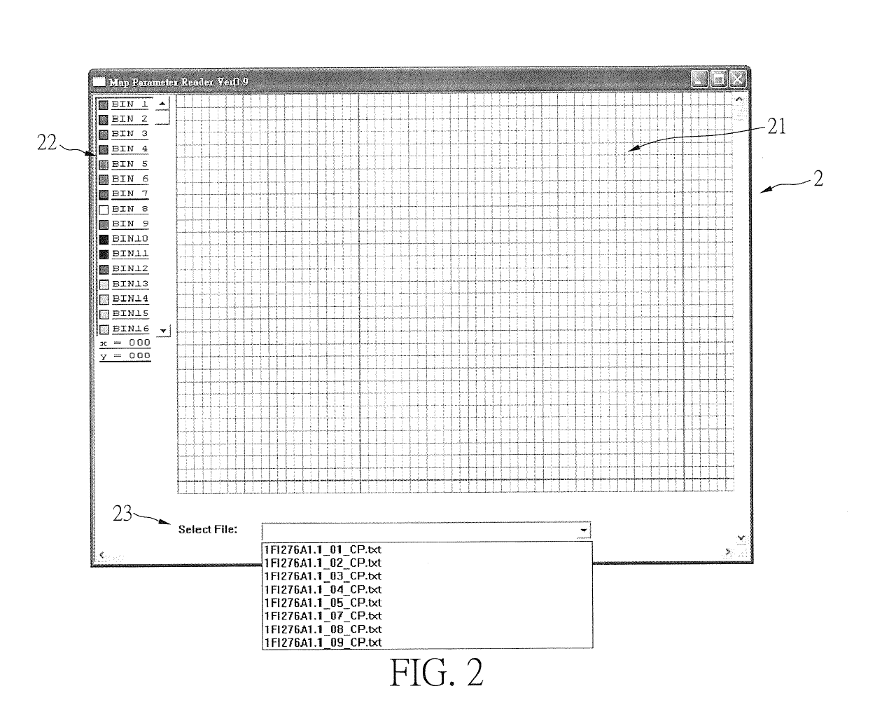

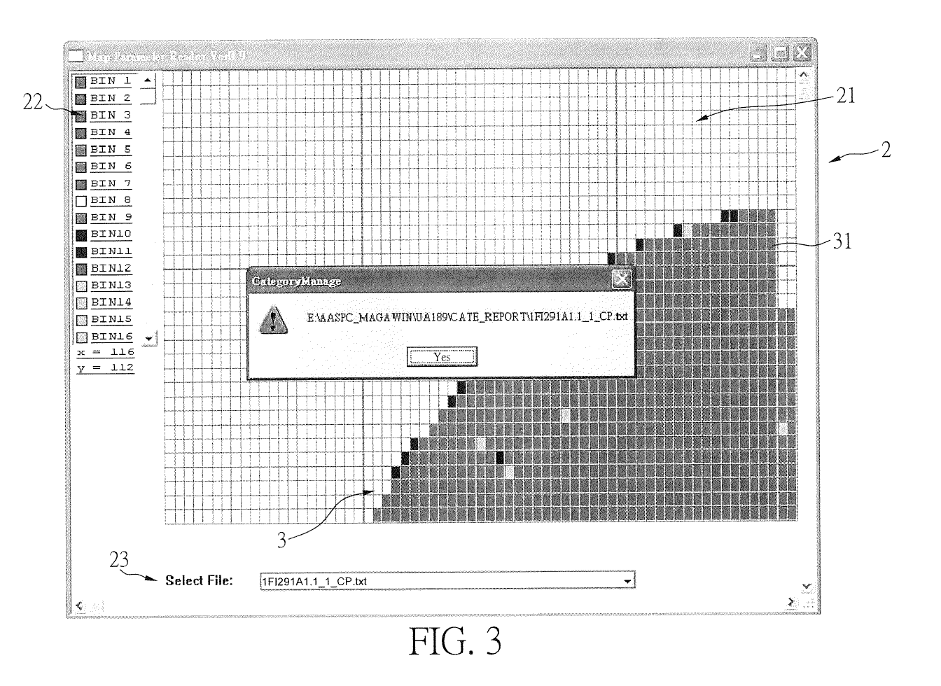

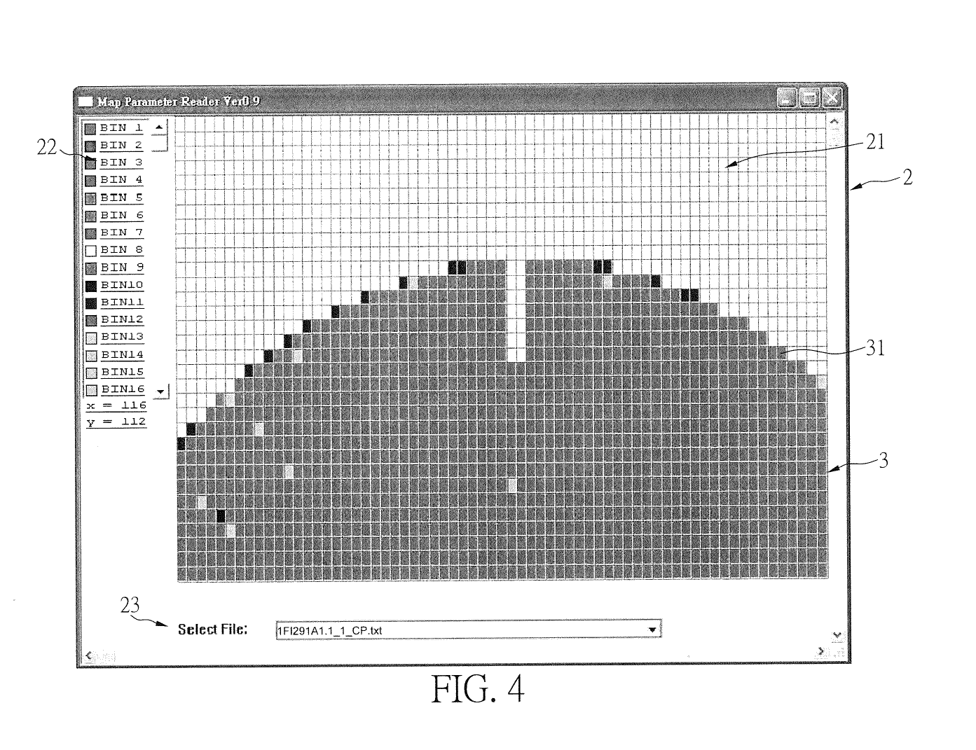

FIGS. 2-10 show the preferred embodiment of the present invention. The execution interface 2 as shown in FIG. 2 has a plurality of partitions 21 to form as grid. The execution interface 2 has a grade area 22 with various grades (BIN1-BIN16) at left side thereof. Besides, a pull down menu 23 is disposed at a bottom of the execution interface 2. The pull down menu 23 is provided for selecting one of wafer files, and a confirmation window is appeared thereafter as shown in FIG. 3; once the confirmation window is confirmed, the display image as shown in FIG. 4 is the wafer map 3 according to the selected wafer file. The color blocks 31 of the wafer map 3 are depending on the grades of the test chips in accordance with the color list in the grade area 22.

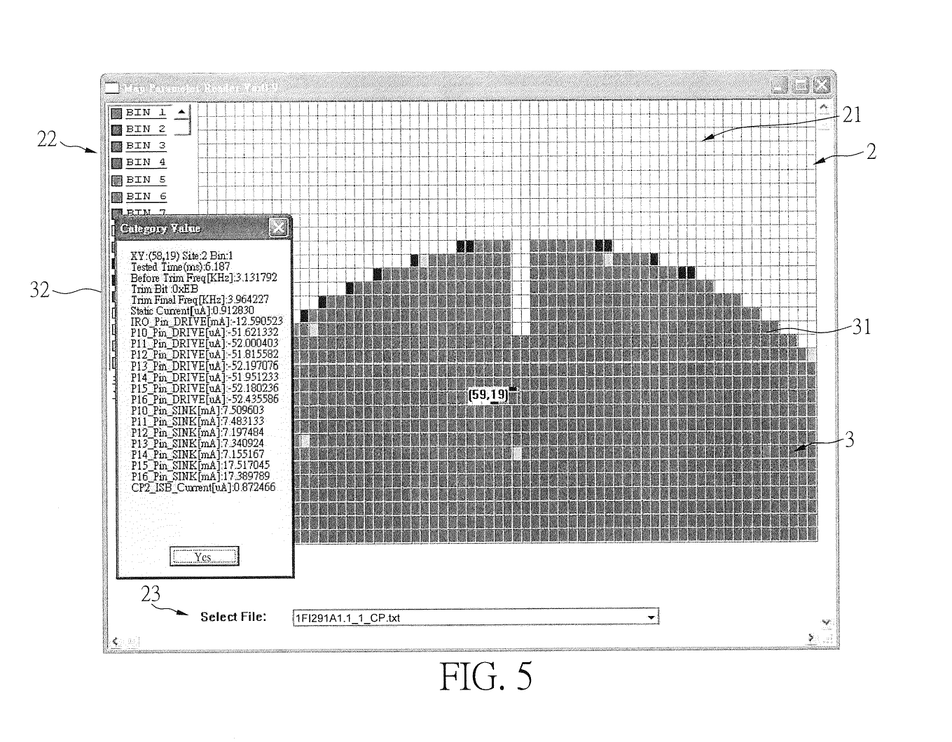

As shown in FIG. 5, when one of the color blocks 31 is selected by the pointer such as a mouse pointer of a computer device, the execution interface 2 reveals the coordinate (58, 19) and once the color block 31 of coordinate (58, 19) is selected, the execution interface 2 would display a window 32 for showing the test data of the associated test chip with respect to the selected color block 31.

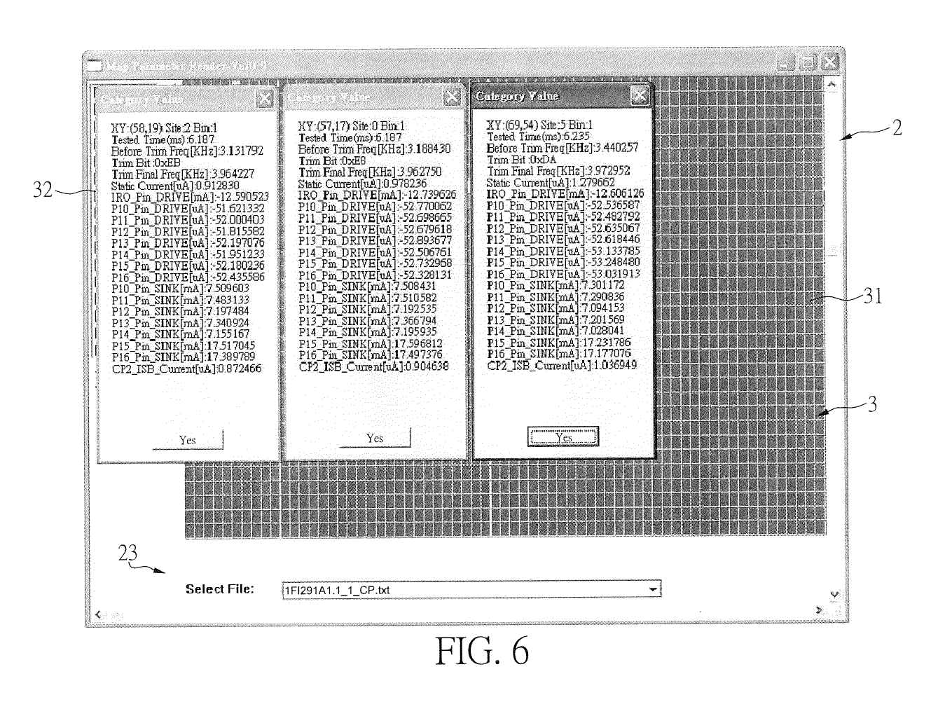

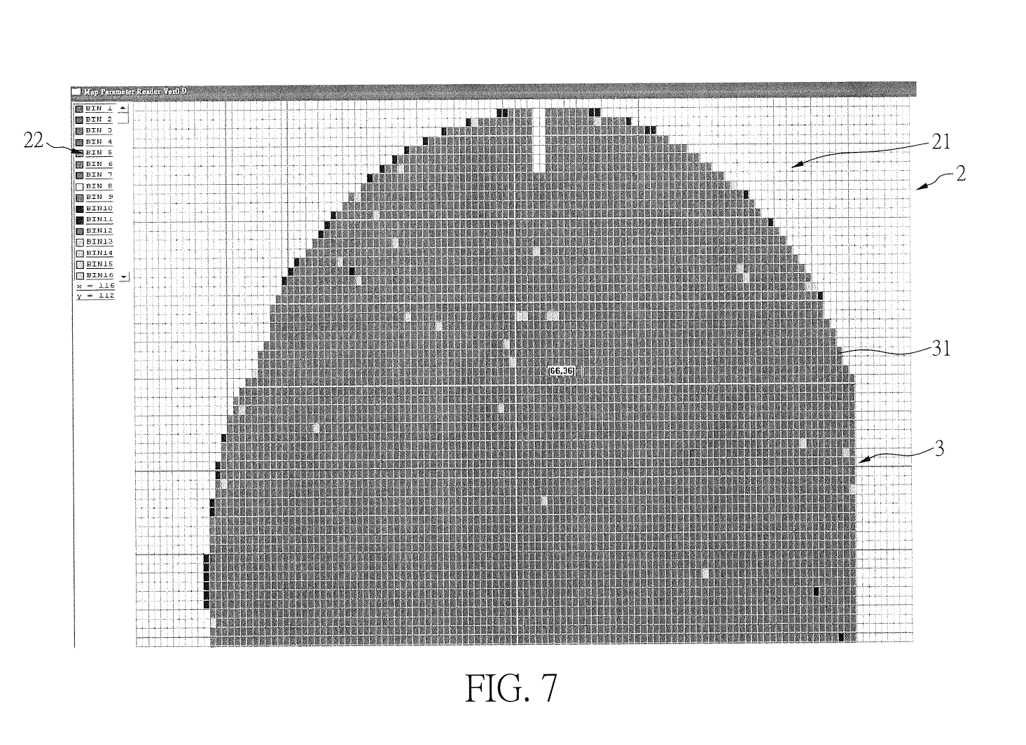

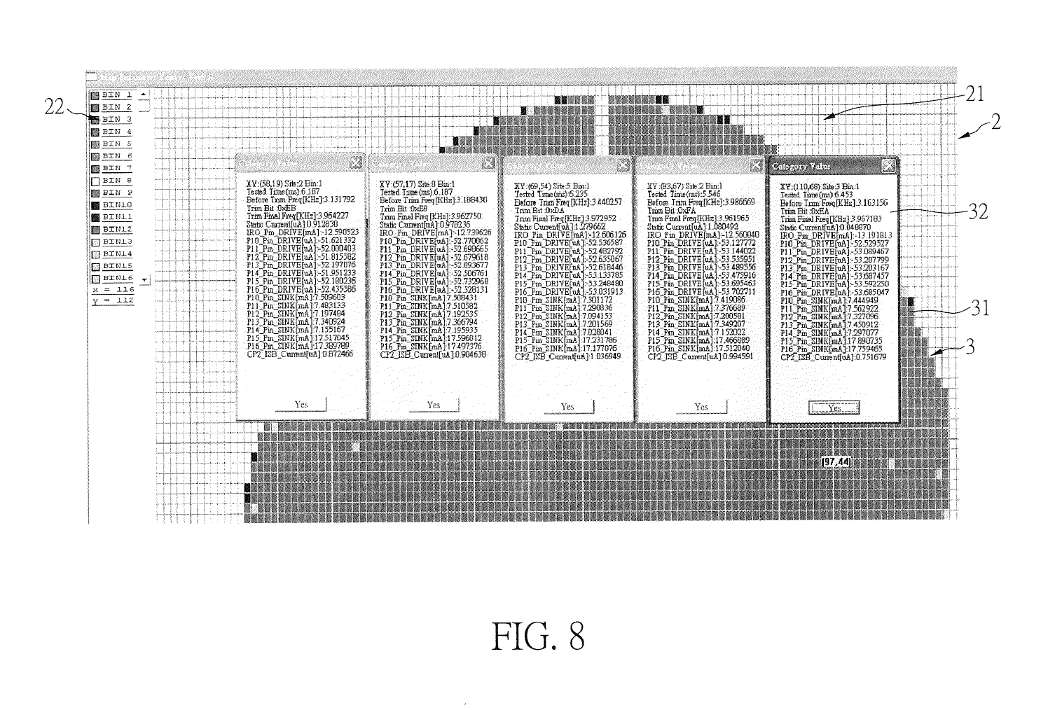

As shown in FIG. 6, the execution interface 2 could display plural windows 32 for showing the test data of various color blocks. The wafer map 3 as shown in FIGS. 2-6 merely shows a partial enlarged view of a small region thereof. For seeing more regions or whole region of the wafer map 3, the wafer map 3 could be reduced for showing more regions, as shown in FIG. 7. Further, as shown in FIG. 8, the execution interface 2 could display more windows 32 for showing the test data of more color blocks 31.

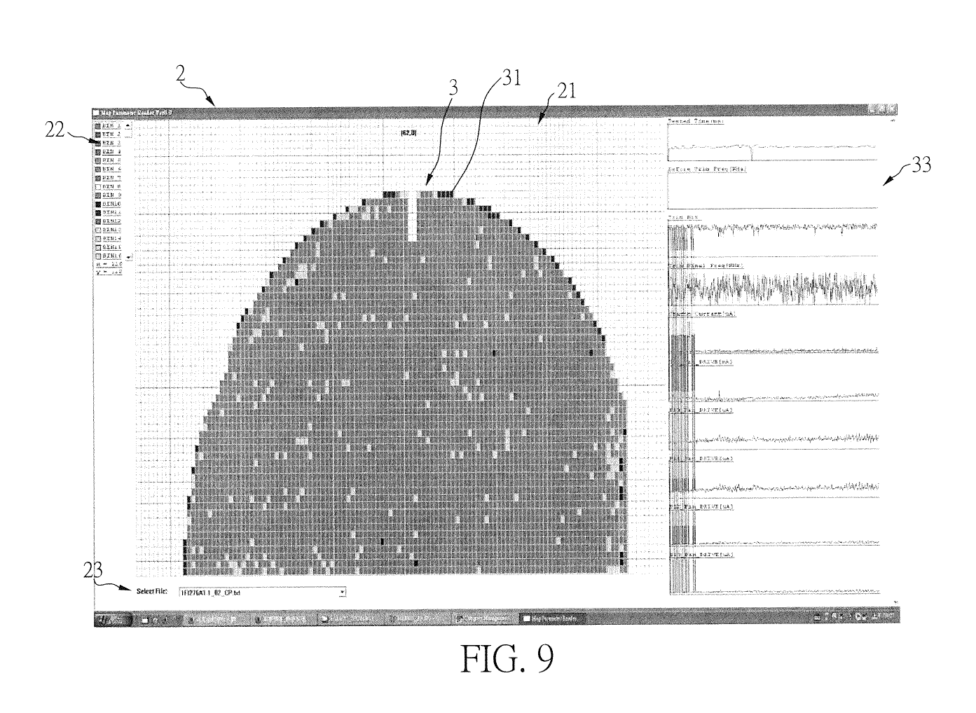

Furthermore, as shown in FIG. 9, the execution interface 2 could display a plurality of curve charts 33 of test results of whole test wafer under various parameters. Each of the curve chats 33 represents one particular test data of the whole test wafer by means of curve chart which differs from the test data displaying in the window 32. Therefore, it is convenient to observe variations of the test data of the test chips of the test wafer under various parameters.

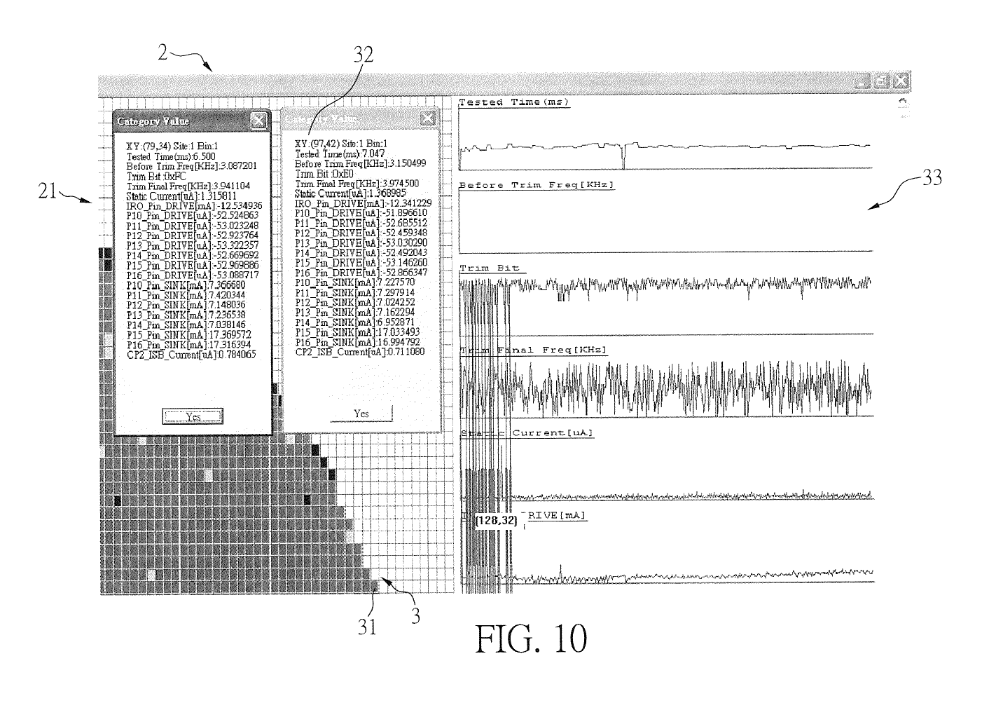

Referring to FIG. 10, the execution interface 2 could show the test data of the respective test chip via the window 32 as one of the color block 31 is selected, or show the curve charts 33 of the test results of whole test wafer under various parameters. Otherwise, above two conditions could display in the execution interface 2 simultaneously such that when any one of the color blocks 31 is selected, the execution interface 2 displays the window 32 for showing the test data of the respective test chip, and the execution interface 2 displays the curve charts 33 of the test results of whole test wafer under various parameters for comparison.

Under this arrangement, when the wafer file is selected and shows the wafer map 3 in the execution interface 2, every color block 31 of the wafer map 3 is presented by specific color with respect to the grade of the associated test chip such that the same color represents same grade, the different colors represent different grades. Comparing to the conventional wafer map which is represented by numeral codes, the wafer map 3 of the present invention is represented by colors to identify grades of the test chips. Specifically, the test data of the test chip with respect to one of the color block 31 could be revealed by selecting the respective color block 31. Besides, the curve charts 33 of the test result of whole test wafer under various parameters could be displayed at the same time. Therefore, the wafer map identification system of the present invention is convenient and rapidly for a user to observe the information of the test data of the test chips.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A wafer map identification system for wafer test data, wherein a test wafer is divided into a plurality of test chips, each of the test chips being tested by a wafer testing device for electrical property to obtain the test data, the wafer map identification system comprising:
a capturing unit configured to collect the test data of each wafer chip from the wafer testing device;
an execution interface for receiving the test data from the capturing unit and generating a wafer map, the wafer map defining a plurality of color blocks with respect to locations of the test chips, each of the color blocks having a color defined by a grade of the respective test chip such that the same grades of the test chips have the same colors, the different grades of the test chips have the different colors;
wherein each color block reveals the associated test data as being selected by a pointer.

2. The wafer map identification system as claimed in claim 1, wherein when one of the color blocks is selected by the pointer, the execution interface displays a window for showing the test data of the associated test chip with respect to the selected color block.

3. The wafer map identification system as claimed in claim 2, wherein the execution interface is provided to display plural windows for showing the test data of various color blocks.

4. The wafer map identification system as claimed in claim 1, wherein the execution interface is provided to display a plurality of curve charts of test results of whole test wafer under various parameters for comparison.

5. The wafer map identification system as claimed in claim 1, wherein when one of the color blocks is selected by the pointer, the execution interface displays a window for showing the test data of the associated test chip with respect to the selected color block; and the execution interface is provided to display a plurality of curve charts of test results of whole test wafer under various parameters for comparison.

6. The wafer map identification system as claimed in claim 1, wherein the wafer map within the execution interface is adapted to be reduced for showing more regions or be partial enlarged for showing a particular region.
